(19) United States
(12) Patent Application Publication
(10) Pub. No.: US 2024/0405180 A1
(43) Pub. Date: Dec. 5, 2024

(54) WIRING SUBSTRATE AND METHOD FOR MANUFACTURING SAME, LIGHT-EMITTING PANEL, AND DISPLAY APPARATUS

(71) Applicants: Hefei BOE Ruisheng Technology Co., Ltd., Hefei, Anhui (CN); BOE Technology Group Co., Ltd., Beijing (CN)

(72) Inventor: Haifeng HU, Beijing (CN)

(21) Appl. No.: 18/698,336

(22) PCT Filed: Jun. 21, 2023
(86) PCT No.: PCT/CN2023/101867

§ 371 Date: Apr. 3, 2024

(30) Foreign Application Priority Data
Jun. 24, 2022 (CN) 202210731172.0

(51) Int. Cl. H01L 33/62; H01L 25/075; H01L 33/60

(52) U.S. Cl. CPC H01L 33/62; H01L 25/0753; H01L 33/60; H01L 2933/0058; H01L 2933/0066

(57) ABSTRACT

Provided in the embodiments of the present disclosure are a wiring substrate and a manufacturing method therefor, a light-emitting panel, and a display apparatus. The wiring substrate comprises: a substrate, a plurality of metal wires and an insulation layer, wherein the metal wires and the insulation layer are located on a same side of the substrate; the insulation layer is located in an area outside the metal wires and a part of the surfaces of the metal wires; the distance between the upper surface of the insulation layer and the substrate is greater than the distance between the upper surfaces of the metal wires and the substrate; the upper surface of the insulation layer can reflect light rays; the insulation layer is provided with first holes, and the first holes expose a part of the surfaces of the metal wires. By means of arranging the insulation layer, a function of protecting the metal wires can be achieved, so as to prevent the metal wires from being oxidized and corroded during a manufacturing process, and improve product performance. In addition, the surface of the insulation layer can reflect light rays, thus improving a light effect.

### CROSS-REFERENCE TO RELATED APPLICATION

This application is a U.S. national stage of international application No. PCT/CN2023/101867, field on Jun. 21, 2023, which claims priority to Chinese Patent Application No. 202210731172.0 filed on Jun. 24, 2022, and entitled “WIRING SUBSTRATE AND MANUFACTURING METHOD THEREFOR, LIGHT-EMITTING PANEL, AND DISPLAY APPARATUS,” the contents of which are herein incorporated by reference in their entireties.

### TECHNICAL FIELD

The present disclosure relates to the field of display technologies, and in particular, relates to a wiring substrate and a method for manufacturing the same, a light-emitting panel, and a display apparatus.

### BACKGROUND

With breakthrough of technology, a light-emitting diode (LED) backlighting system is applicable to display products such as TVs, monitors, computers, and the like. LED backlighting includes a wiring substrate and an LED connected to the wiring substrate.

### SUMMARY

Embodiments of the present disclosure provide a wiring substrate and a method for manufacturing the same, a light-emitting panel, and a display apparatus.

According to some embodiments of the present discloser, a wiring substrate is provided. The wiring substrate includes:
a substrate;
a plurality of metal traces disposed on a side of the substrate; and
an insulative layer disposed on the same side of the substrate as the plurality of metal traces, wherein the insulative layer is disposed in a region other than the metal traces and on a portion of surfaces of the metal traces, a distance between a surface, away from the substrate, of the insulative layer and the substrate is greater than a distance between a surface, away from the substrate, of the metal trace and the substrate, the surface, away from the substrate, of the insulative layer is capable of reflecting light, and a first aperture is formed in the insulative layer, the first aperture exposing a portion of the surface of each of the metal traces.

In some embodiments, a material of the insulative layer includes white ink, and the insulative layer covers the metal traces at locations other than the first aperture.

In some embodiments, the insulative layer includes a photoresist layer and a reflective layer; wherein the photoresist layer is disposed in the region other than the metal traces, and the first aperture includes a first sub-aperture, the first sub-aperture running through the photoresist layer; and the reflective layer is at least disposed on a surface of a side, away from the substrate, of the photoresist layer.

In some embodiments, the reflective layer covers the photoresist layer and the metal traces, the first aperture includes a second sub-aperture, the second sub-aperture running through the reflective layer, and an overlapping region being present between an orthographic projection of the second sub-aperture on the substrate and an orthographic projection of the first sub-aperture on the substrate.

In some embodiments, a material of the reflective layer includes white ink.

In some embodiments, each of the metal traces includes a body metal layer and an alloy layer that are stacked, wherein the alloy layer is disposed on a surface, away from the substrate, of the body metal layer.

In some embodiments, a thickness of each of the metal traces ranges from 5 μm to 8.5 μm.

In some embodiments, the wiring substrate further includes an oxidation protective layer, wherein the oxidation protective layer is disposed in an exposed region of the metal trace, the oxidation protective layer is in direct contact with the metal trace, a material of the oxidation protective layer includes nickel and gold, and a thickness of the oxidation protective layer ranges from 4 μm to 5 μm.

In some embodiments, the wiring substrate further includes an inorganic protective layer, wherein the inorganic protective layer covers the metal traces and an exposed surface of the substrate, the insulative layer is disposed on a side, facing away from the substrate, of the inorganic protective layer, and a second aperture is formed in the inorganic protective layer, an overlapping region being present between an orthographic projection of the second aperture on the substrate and an orthographic projection of the first aperture on the substrate.

In some embodiments, a material of the inorganic protective layer includes one or more of silicon oxide, silicon nitride, or silicon oxynitride.

In some embodiments, the plurality of metal traces include a power signal line, an address signal line, a common voltage signal line, a cascade line, and a feedback signal line; the plurality of metal traces form a plurality of first pad groups and a plurality of second pad groups through a surface exposed by the first aperture, wherein the plurality of first pad groups are configured to be coupled to a micro driver chip, and the plurality of second pad groups are configured to be coupled to a light-emitting element; each of the plurality of first pad groups includes a power supply pad, an output pad, an address pad, and a ground pad, wherein the power supply pad is connected to the power signal line, the ground pad is connected to the common voltage signal line, and the output pad is connected to at least one pad of one of the second pad groups; and the plurality of first pad groups are cascaded, and in the plurality of cascaded first pad groups, the address pad of a first one of the first pad groups is connected to the address signal line, the output pad of a last one of the first pad groups is connected to the feedback signal line, and the output pad of the first pad group of an n^{th} cascaded one of the first pad groups is connected to the address pad of the first pad group of a (n+1)^{th} cascaded one of the first pad groups by one of the cascade lines, wherein n is a positive integer.

According to some embodiments of the present discloser, a method for preparing a wiring substrate is provided. The method includes:
forming a plurality of metal traces on a side of a substrate; and
forming an insulative layer on the side, on which the plurality of metal traces are formed, of the substrate, wherein the insulative layer is disposed in a region other than the metal traces and on a portion of surfaces of the metal traces, a distance between a surface of a side, away from the substrate, of the insulative layer and the substrate is greater than a distance between a surface of a side, distal form the substrate, of the metal trace and the substrate, the surface, away from the substrate, of the insulative layer is capable of reflecting light, and a first aperture is formed in the insulative layer, the first aperture exposing a portion of the surface of each of the metal traces.

In some embodiments, forming the plurality of metal traces on the side of the substrate includes:
forming a body metal film with a predetermined thickness on a side of the substrate;
acquiring a metal film including the body metal film and an alloy film by depositing the alloy film on a surface, away from the substrate, of the body metal film;
forming a plurality of first photoresist bodies spaced apart by coating a first photoresist on a side, facing away from the substrate, of the metal film and using a first mask to expose and develop the first photoresist; and
acquiring the plurality of metal traces by etching the metal film other than the first photoresist bodies and stripping the first photoresist bodies.

In some embodiments, forming the body metal film with the predetermined thickness on the side of the substrate includes:
forming the body metal film with the predetermined thickness on the side of the substrate by using a deposition process multiple times; or
acquiring the body metal film with the predetermined thickness by depositing a first metal film on the side of the substrate and forming a second metal film on a surface, away from the substrate, of the first metal film using an electroplating process, wherein the body metal film includes the first metal film and the second metal film that are stacked.

In some embodiments, the insulative layer is white ink; and forming the insulative layer on the side, facing toward the plurality of metal traces, of the substrate includes:
depositing an inorganic protective layer on the side, facing toward the plurality of metal traces, of the substrate, wherein the inorganic protective layer covers the metal traces and the substrate;
forming white ink on a side, facing away from the substrate, of the inorganic protective layer by using a screen printing process, wherein the first aperture is formed in the white ink; and
forming a second aperture in the inorganic protective layer by using a screen-printing wet-etching process.

In some embodiments, the insulative layer includes a photoresist layer and a reflective layer, and the first aperture includes a first sub-aperture and a second sub-aperture; and forming the insulative layer on the side, facing toward the plurality of metal traces, of the substrate includes:
coating a second photoresist on the side, facing toward the plurality of metal traces, of the substrate, and forming a photoresist patterned region and a hollow-out region by using a first mask, wherein the second photoresist in the photoresist patterned region forms the photoresist layer, the hollow-out region forms the first sub-aperture, and one of the second photoresist and the first photoresist is a positive photoresist and the other is a negative photoresist; and
forming the reflective layer on a side, away from the substrate, of the photoresist layer by using a screen printing process, wherein the second sub-aperture is formed in the reflective layer, an overlapping region being present between an orthographic projection of the second sub-aperture on the substrate and an orthographic projection of the first sub-aperture on the substrate.

In some embodiments, the insulative layer includes a photoresist layer and a reflective layer, and the first aperture includes a first sub-aperture and a second sub-aperture; and forming the insulative layer on the side, facing toward the plurality of metal traces, of the substrate includes:
depositing an inorganic protective layer on the side, facing toward the plurality of metal traces, of the substrate, wherein the inorganic protective layer covers the metal traces and the substrate;
coating a second photoresist on a side, facing toward the inorganic protective layer, of the substrate, and forming a photoresist patterned region and a hollow-out region by using a first mask, wherein the second photoresist in the photoresist patterned region forms the photoresist layer, the hollow-out region forms the first sub-aperture, and one of the second photoresist and the first photoresist is a positive photoresist and the other is a negative photoresist;
forming a second aperture by removing at least a portion of the exposed inorganic protective layer using a screen-printing wet-etching process; and
forming the reflective layer on a side, away from the substrate, of the photoresist layer by using a screen printing process, wherein the second sub-aperture is formed in the reflective layer.

In some embodiments, the method further includes performing an electroless nickel immersion gold process on exposed surfaces of the metal traces.

According to some embodiments of the present discloser, a light-emitting panel is provided. The light-emitting panel includes the wiring substrate as described above and a plurality of light-emitting diode chips, wherein the plurality of light-emitting diode chips are correspondingly connected to metal traces.

According to some embodiments of the present discloser, a display device is provided. The display device includes the light-emitting panel as described above.

### BRIEF DESCRIPTION OF DRAWINGS

In the accompanying drawings, unless otherwise defined, the same reference numeral throughout the plurality of accompanying drawings indicates the same or similar parts or elements. These accompanying drawings are not necessarily drawn to scale. It should be understood that these accompanying drawings depict only some implementations in accordance with the present disclosure and shall not be considered a limitation on the scope of the present disclosure.

FIG. 1 is a schematic structural diagram of a cross section of a wiring substrate according to some embodiments of the present disclosure;

FIG. 2 is a schematic structural diagram of a cross section of another wiring substrate according to some embodiments of the present disclosure;

FIG. 3 is a schematic structural diagram of a cross section of yet another wiring substrate according to some embodiments of the present disclosure;

FIG. 4 is a schematic diagram of a partial structure of a wiring substrate according to some embodiments of the present disclosure;

FIG. 5 is an enlarged schematic diagram of a portion M of FIG. 4;

FIG. 6 is a schematic diagram of a wiring substrate according to some embodiments of the present disclosure after a metal film is formed in the wiring substrate;

FIG. 7 is a schematic diagram of a wiring substrate according to some embodiments of the present disclosure after a first photoresist is formed in the wiring substrate;

FIG. 8 is a schematic diagram of a wiring substrate according to some embodiments of the present disclosure after a metal trace is formed in the wiring substrate;

FIG. 9 is a schematic diagram of a wiring substrate according to some embodiments of the present disclosure after an inorganic protective layer is formed in the wiring substrate;

FIG. 10 is a schematic diagram of a wiring substrate according to some embodiments of the present disclosure after white ink is formed in the wiring substrate;

FIG. 11 is a schematic diagram of a wiring substrate according to some embodiments of the present disclosure after a second aperture and white ink are formed in the wiring substrate;

FIG. 12 is a schematic diagram of a wiring substrate according to some other embodiments of the present disclosure after a second aperture is formed in an inorganic protective layer;

FIG. 13 is a schematic diagram of a wiring substrate according to some embodiments of the present disclosure after a photoresist layer is formed in the wiring substrate;

FIG. 14 is a schematic diagram of a wiring substrate according to some embodiments of the present disclosure after a reflective layer is formed in the wiring substrate;

FIG. 15 is a schematic diagram of some embodiments of the present disclosure after a photoresist layer is formed;

FIG. 16 is a schematic diagram of a wiring substrate according to some embodiments of the present disclosure after a second aperture is formed in an inorganic protective layer;

FIG. 17 is a schematic diagram of some embodiments of the present disclosure after a reflective layer and a second aperture are formed; and

FIG. 18 is a schematic diagram of some other embodiments of the present disclosure after a reflective layer is formed.

### REFERENCE NUMERALS THEREOF

11—substrate; 12—metal trace; 121—body metal layer; 122—alloy layer; 13—first photoresist; 14—inorganic protective layer; 140—second aperture; 15—insulative layer; 150—first aperture; 151—photoresist layer; 151a—first sub-aperture; 152—reflective layer; 152a—second sub-aperture; 16—oxidation protective layer.

### DETAILED DESCRIPTION

Only certain exemplary embodiments are briefly described hereinafter. As may be recognized by those skilled in the art, the described embodiments may be modified in a variety of different ways without departing from the spirit or scope of the present disclosure, and different embodiments may be combined in any manner without conflict. Accordingly, the accompanying drawings and descriptions are considered to be essentially exemplary and not limiting.

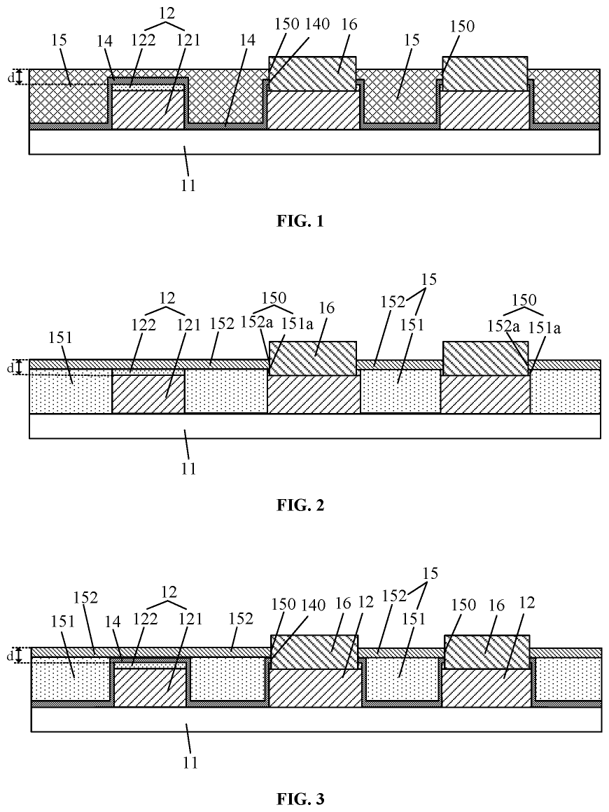

FIG. 1 is a schematic structural diagram of a cross section of a wiring substrate according to some embodiments of the present disclosure. As shown in FIG. 1, the wiring substrate includes a substrate 11, a plurality of metal traces 12, and an insulative layer 15. The plurality of metal traces 12 are disposed on a side of the substrate 11.

The insulative layer 15 is disposed on a side, facing toward the metal traces 12, of the substrate 11. That is, the insulative layer 15 is disposed on the same side of the substrate 11 as the metal traces 12. The insulative layer 15 is disposed at least in a region other than the metal traces 12. For example, the insulative layer 15 is disposed in the region other than the metal traces 12 and on a portion of surfaces of the metal traces 12. A distance between a surface, away from the substrate 11, of the insulative layer 15 and the substrate 11 is greater than a distance between a surface, away from the substrate 11, of the metal trace 12 and the substrate 11. In some embodiments, the surface, away from the substrate 11, of the insulative layer 15 is capable of reflecting light. A first aperture 150 is formed in the insulative layer 15, and the first aperture 150 exposes a portion of the surface of the metal trace 12.

In some embodiments, the exposed surface of the metal trace 12 is configured to connect to an electronic component. The electronic component includes at least one of a light-emitting diode chip, a micro driver chip, a sensor chip, or the like.

In some embodiments, the light-emitting diode chip is a mini light-emitting diode (Mini LED) chip, or a micro light-emitting diode (Micro LED) chip.

In some embodiments, the metal trace 12 includes a body metal layer 121 and an alloy layer 122 arranged cascaded. The alloy layer 122 is disposed on a surface, away from the substrate 11, of the body metal layer 121. The alloy layer 122 is a corrosion-resistant alloy layer.

In the wiring substrate of some embodiments of the present disclosure, the alloy layer 122 protects the body metal layer 121, such that the body metal layer 121 is prevented from being eroded by water and oxygen during the process. The insulative layer 15 protects the sidewall of the metal trace 12, such that the metal trace 12 is prevented from being eroded by water and oxygen during the process. By providing the alloy layer 122 and the insulative layer 15, the metal trace 12 is fully protected, which prevents the metal trace 12 from being oxidized and corroded during the process, and thus the product performance is improved. In addition, the surface of the insulative layer 15 is capable of reflecting light, and thus in a case where a light-emitting device is provided on the wiring substrate, the light emitted by the light-emitting device to the surface of the wiring substrate is reflected by the insulative layer 15 to the light-exit side, such that the light efficiency is improved.

In some embodiments, the material of the substrate 11 includes glass or resin (or other materials of printed circuit board (PCB)).

In some embodiments, the material of the body metal layer 121 includes but is not limited to copper. Copper is characterized by low resistivity and good electrical conductivity. The material of the alloy layer 122 includes nickel and copper. For example, the material of the alloy layer 122 includes a nickel-copper alloy, a nickel-vanadium alloy, a nickel-tungsten alloy, or a tungsten-nickel alloy.

It should be noted that in other embodiments, the metal trace 121 is a single-layer structure. For example, the metal trace 121 is a single metal layer of a single alloy layer.

In some embodiments, as shown in FIG. 1, the wiring substrate further includes an inorganic protective layer 14. The inorganic protective layer 14 is disposed on a side, facing away from the substrate 11, of the metal traces 12, and the inorganic protective layer 14 covers the metal traces 12 and the exposed surface of the substrate 11 (i.e., the surface not covered by the metal traces 12). The insulative layer 15 is disposed on a side, facing away from the substrate 11, of the inorganic protective layer 14. The inorganic protective layer 14 provides further protection to the metal trace 12, which prevents water and oxygen from invading the metal trace 12 during the process of preparing the insulative layer 15.

In some embodiments, a second aperture 140 is formed in the inorganic protective layer 14, and an orthographic projection of the second aperture 140 on the substrate 11 is at least partially overlapped with an orthographic projection of the first aperture 150 on the substrate 11. The overlapped region of the second aperture 140 and the first aperture 150 exposes a portion of the surface of the metal trace 12.

In some embodiments, the material of the inorganic protective layer 14 includes any one or more of silicon oxide (SiOx), silicon nitride (SiNx), or silicon oxynitride (SiON). The inorganic protective layer 14 is a single layer, a multiple layer, or a composite layer.

A thickness of the inorganic protective layer 14 is defined as desired. In some embodiments, the thickness of the inorganic protective layer 14 ranges from 8% to 12.5% of a thickness of the metal trace 12. For example, the thickness of the inorganic protective layer 14 is not greater than 10% of the thickness of the metal trace 12.

In some embodiments, as shown in FIG. 3, the material of the insulative layer 15 includes white ink, and the insulative layer 15 covers the metal traces 12 at locations other than the first aperture 150. In this way, other than the first aperture 150, the white ink protects both the sidewall and the upper surface of the metal trace 12, such that the metal trace 12 is prevented from being eroded by water and oxygen. In addition, the white ink also has a reflective function that reflects light irradiated to the surface of the white ink toward the light-exit side. By adopting white ink as the insulative layer 15, the insulative layer with the reflective function is acquired, which is favorable for improving productivity and reducing cost.

FIG. 2 is a schematic structural diagram of a cross section of another wiring substrate according to some embodiments of the present disclosure. The structure of the wiring substrate in FIG. 2 is the same as the structure of the wiring substrate in FIG. 1, with the difference that the insulative layer 15 in FIG. 2 includes a photoresist layer 151 and a reflective layer 152, and the photoresist layer 151 is disposed in a region other than the metal traces 12. The first aperture 150 includes a first sub-aperture 151a, and the first sub-aperture 151a penetrates the photoresist layer 151. In some embodiments, the first sub-aperture 151a exposes an entire surface, away from the substrate 11, of the metal trace 12. In some embodiments, the reflective layer 152 is provided at least on a surface, away from the substrate 11, of the photoresist layer 151. In this case, the insulative layer 15 is a composite layer of the photoresist layer 151 and the reflective layer 152, which provides double protection and further prevents the metal trace 12 from being eroded by water and oxygen.

In some embodiments, the reflective layer 152 covers the metal traces 12 and the photoresist layer 151. The first aperture 150 includes a second sub-aperture 152a, and the second sub-aperture 152a runs through the reflective layer 152. An orthographic projection of the second sub-aperture 152a on the substrate 11 is within an orthographic projection of the first sub-aperture 151a on the substrate 11, such that a portion of the surface of the metal trace 12 is exposed by the second sub-aperture 152a.

In some embodiments, the material of the reflective layer 152 includes white ink.

FIG. 3 is a schematic structural diagram of a cross section of yet another wiring substrate according to some embodiments of the present disclosure. The structure of the wiring substrate in FIG. 3 is the same as the structure of the wiring substrate in FIG. 2, with the difference that the wiring substrate in FIG. 3 further includes the inorganic protective layer 14. For relevant contents of the inorganic protective layer 14, reference is made to the relevant embodiments of FIG. 1, which are not repeated herein.

In some embodiments, the thickness of the metal trace 12 ranges from 5 μm to 8.5 μm (including endpoint values). For example, the thickness of the metal trace 12 is one of 5 μm, 5.5 μm, 6 μm, 6.5 μm, 7 μm, 7.5 μm, 8 μm, and 8.5 μm. The thickness of the metal trace 12 is sufficiently large to reduce the resistance of the metal trace 12.

In some embodiments, as shown in FIG. 1 to FIG. 3, the wiring substrate further includes an oxidation protective layer 16. The oxidation protective layer 16 is disposed in the exposed region of the metal trace 12, and the oxidation protective layer 16 is in direct contact with the metal trace 12. In some embodiments, the oxidation protective layer 16 covers the exposed region of the metal trace 12. The oxidation protective layer 16 prevents the exposed region of the metal trace 12 from being oxidized.

In some embodiments, the material of the oxidation protective layer 16 includes nickel and gold. A thickness of the oxidation protective layer 16 ranges from 4 μm to 5 μm. It should be noted that the light-emitting diode chip or the micro driver chip is connected to the metal trace 12 through the oxidation protective layer 16 by a die bonding process. Such an oxidation protective layer 16 not only better prevents the metal trace 12 from being oxidized and eroded, but also improves the die bonding yield.

In some embodiments, as shown in FIG. 1 to FIG. 3, a step d between the surface, away from the substrate 11, of the insulative layer 15 and the surface, away from the substrate 11, of the metal trace 12 is less than or equal to 10 μm, which facilitates the subsequent die bonding or bonding process and improves the yield rate.

It should be noted that each region of the metal trace 12 covered by the oxidation protective layer 16 and the oxidation protective layer 16 above the corresponding region form a pad. After a reflow process, each pad is electrically connected to one pin of an electronic component by a weld metal. The weld metal includes tin and the like. In some embodiments, the electronic component includes at least one of a light-emitting diode chip, a micro driver chip, a sensor chip, or the like.

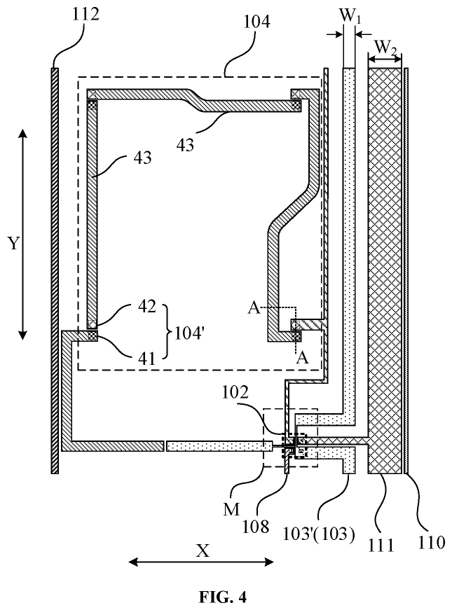

FIG. 4 is a schematic diagram of a partial structure of a wiring substrate according to some embodiments of the present disclosure. FIG. 5 is an enlarged schematic diagram of a portion M of FIG. 4. The aforementioned FIG. 1 to FIG. 3 are schematic structural diagrams of the section along a line A-A in FIG. 4, respectively.

In some embodiments, as shown in FIG. 4 and FIG. 5, the wiring substrate includes a first pad group 102 and a second pad group 104. In some embodiments, the first pad group 102 is coupled to the micro driver chip, and the second pad group 104 is coupled to the LED chip. In some embodiments, each first pad group 102 is coupled to one micro driver chip, and each second pad group 104 is coupled to a plurality of LED chips.

The metal traces 12 include a power signal line 103. The first pad group 102 includes a power supply pad Pwr and an output pad Out. The power signal line 103 is coupled to the power supply pad Pwr. The second pad group 104 includes a plurality of sub-pad groups 104′ electrically connected to each other, and each of the sub-pad groups 104′ includes at least a first sub-pad 41 and a second sub-pad 42. Each of the sub-pad groups 104′ is coupled to one LED chip. The first sub-pad 41 of at least one sub-pad group 104′ in each second pad group 104 is coupled to the power signal line 103. The second sub-pad 42 of at least one sub-pad group 104′ in each second pad group 104 is coupled to the output pad Out in one first pad group 102.

In some embodiments, in FIG. 4, the second pad group 104 includes four sub-pad groups 104′. The first sub-pad 41 of the lower left sub-pad group 104′ is coupled to the power signal line 103, and the second sub-pad 42 of the lower right sub-pad group 104′ is coupled to the output pad Out in the first pad group 102. Along a clockwise direction, in adjacent two sub-pad groups 104′, the second sub-pad 42 of the previous sub-pad group 104′ is coupled to the first sub-pad 41 of the next sub-pad group 104′ by a connection line 43.

In the wiring substrate shown in FIG. 4, the first pad group 102 and the second pad group 104 are connected to the same power signal line 103.

As shown in FIG. 4 and FIG. 5, the metal traces 12 further include a first connection lead 106. The power signal line 103 includes a plurality of sub-segments 103′, and adjacent two of the sub-segments 103′ are connected to each other by one first connection lead 106.

As shown in FIG. 4 and FIG. 5, the metal traces 12 further include a second connection lead 107. In some embodiments, the second connection lead 107 is structured integrally with the first connection lead 106. The second connection lead 107 is configured to connect the power signal line 103 to the second pad group 104.

In some embodiments, as shown in FIG. 5, the first pad group 102 further includes an address pad Di and a ground pad Gnd. The address pad Di and the power supply pad Pwr which belong to the same first pad group 102 are spaced apart in a first direction X and spaced apart with the output pad Out in a second direction Y. The second direction Y is perpendicular to the first direction X. The ground pad Gnd and the power supply pad Pwr are spaced apart in the second direction Y and spaced apart with the output pad Out in the first direction X. In some embodiments, the output pad Out is disposed in the upper left corner of the first pad group 102, the address pad Di is disposed in the lower left corner of the first pad group 102, the ground pad Gnd is disposed in the upper right corner of the first pad group 102, and the power supply pad Pwr is disposed in the lower right corner of the first pad group 102.

In some embodiments, the address pad Di receives address signals to strobe a micro driver chip of a corresponding address. The power supply pad Pwr provides the micro driver chip with a first operating voltage and communication data. The communication data is configured to control the luminous intensity of the corresponding light-emitting element (i.e., the LED chip). The output pad Out outputs relay signals and drive signals at different periods, respectively. In some embodiments, the relay signal is an address signal supplied to the address pad Di in first pad group 102 of the next cascade, and the drive signal is a drive current used to drive the light-emitting element coupled to the first pad group 102 in which the output pad Out is located to emit light. The ground pad Gnd receives common voltage signals.

In some embodiments, a plurality of first pad groups 102 are provided. The plurality of first pad groups 102 are cascaded. As shown in FIG. 4, the metal traces 12 further include an address signal line 108. One address signal line 108 is coupled to the address pad Di of a first one of the plurality of cascaded first pad groups 102.

As shown in FIG. 5, the metal traces 12 further include a cascade line 109. The cascade line 109 is configured to connect the output pad Out of the first pad group 102 of an n^{th} cascaded one of the first pad groups to the address pad Di of the first pad group 102 of a (n+1)^{th} cascaded one of the first pad groups, wherein the first pad group 102 of the n^{th} cascaded first pad group and the first pad group 102 of the (n+1)^{th} cascaded first pad group belong to the same pad region. in this way, the relay signal outputted from the output pad Out of the first pad group 102 of the n^{th} cascaded first pad group is supplied to the address pad Di of the first pad group 102 of the (n+1)^{th} cascaded first pad group by the cascade line 109, wherein n is a positive integer.

As shown in FIG. 4, the metal traces 12 further include a feedback signal line 110. One feedback signal line 110 is coupled to the output pad Out of a last one of the plurality of cascaded first pad groups 102.

As shown in FIG. 4 and FIG. 5, the metal traces 12 further include a common voltage signal line 111. One common voltage signal line 111 is coupled to the ground pads Gnd of all first pad groups 102 within one pad region. A line width W2 of the common voltage signal line 111 is greater than 1 mm and less than or equal to 2.5 mm.

In FIG. 4 and FIG. 5, the different metal traces 12, i.e., the power signal line 103, the first connection lead 106, the second connection lead 107, the address signal line 108, the cascade line 109, the feedback signal line 110, and the common voltage signal line 111, are represented using different fills. It should be noted that the power signal line 103, the first connection lead 106, the second connection lead 107, the address signal line 108, the cascade line 109, the feedback signal line 110, and the common voltage signal line 111 are formed simultaneously using the same process, i.e., formed using the same patterning process.

In some embodiments, as shown in FIG. 4, the metal traces 12 further include an electrostatic discharge (ESD) trace 112 disposed at a periphery, for ESD protection of the wiring substrate. Specifically, the ESD trace 112 is disposed at the periphery of any signal line, any connection line, any trace, the first pad group 102, and the second pad group 104, and the ESD trace 112 forms a ring-like structure.

Some embodiments of the present disclosure also provide a light-emitting panel. The light-emitting panel includes the wiring substrate and the light-emitting diode chip according to any of the embodiments of the present disclosure, and the light-emitting diode chip is connected to the corresponding metal trace 12.

Some embodiments of the present disclosure also provide a display device. The display device includes the light-emitting panel according to any of the embodiments of the present disclosure.

The light-emitting panel according to the embodiments of the present disclosure is assembled in the display device as a display panel or is assembled in the display device as a light source. The display device is an electronic paper, a smartphone, a tablet computer, a television, a monitor, a laptop computer, a digital photo frame, a navigator, a wearable display device, or any other product or component with a display function.

The light-emitting panel according to the embodiments of the present disclosure is also used as a light-emitting light source in a lighting product.

Some embodiments of the present disclosure also provide a method for preparing a wiring substrate. The method includes: forming a plurality of metal traces on a side of the substrate; and forming an insulative layer on the side of the substrate where the metal traces are formed.

The insulative layer is disposed in a region at least other than the metal traces. A distance between a surface of a side, away from the substrate of the insulative layer and the substrate is greater than a distance between a surface of a side, away from the substrate, of the metal trace and the substrate. The surface, away from the substrate, of the insulative layer is capable of reflecting light. A first aperture is formed in the insulative layer, and the first aperture exposes a portion of the surface of each of the metal traces.

The technical solution of some embodiments of the present disclosure is described in detail hereinafter by a preparing process of a wiring substrate according to some embodiments of the present disclosure. It should be understood that concerning the term “patterning” referred to herein, in a case where the patterned material is an inorganic material or a metal, the term “patterning” includes processes such as coating photoresist, mask exposure, developing, etching, and stripping photoresist, and in a case where the patterned material is an organic material, the term “patterning” includes processes such as mask exposure and developing. The terms “evaporation,” “deposition,” “coating,” and “overlay” described herein are all mature preparation processes in the related art.

In S10, a body metal film 121′ with a predetermined thickness is formed on a side of the substrate 11.

In some embodiments, the predetermined thickness ranges from 5 μm to 8.5 μm. Step S10 includes: forming the body metal film 121′ with the predetermined thickness on the side of the substrate 11 by employing a deposition process multiple times. It should be understood that one layer of a sub-body metal film is formed on a side of the substrate 11 by employing the deposition process once, and in view of the limitation of the deposition process, a thickness of the sub-body metal film acquired by deposition each time is thin. Therefore, to acquire the body metal film with the pre-determined thickness, the deposition process is employed multiple times, such that two or more layers of stacked sub-body metal films are acquired, and thus the body metal film 121′ with the pre-determined thickness is acquired.

In some embodiments, to acquire the body metal film 121′ with the predetermined thickness, step S10 includes: depositing a first metal film on a side of the substrate 11, using the first metal film as a seed layer, and forming a second metal film (referred to as an electroplating metal film) on a surface, away from the substrate 11, of the first metal film by using an electroplating process. The second metal film with a desirable thickness is acquired by using the electroplating process, and the thickness of the second metal film is controlled by controlling a period of the electroplating process, such that the sum of the thicknesses of the first metal film and the second metal film is controlled, and thus the body metal film 121′ with the predetermined thickness is acquired. The body metal film 121′ includes the first metal film and the second metal film that are stacked.

In some embodiments, before forming the body metal film 121′, a buffer layer (not shown in the figures) is formed on a side of the substrate 11, and then the body metal film 121′ is formed on the buffer layer. The material of the buffer layer includes any one or more of silicon oxide (SiOx), silicon nitride (SiNx), or silicon oxynitride (SiON). The buffer layer is a single layer, a multilayer, or a composite layer. The resistance of the substrate 11 to water and oxygen is improved by the buffer layer.

In S20, a metal film 12′ is acquired by depositing an alloy film 122′ on a surface, away from the substrate 11, of the body metal film 121′.

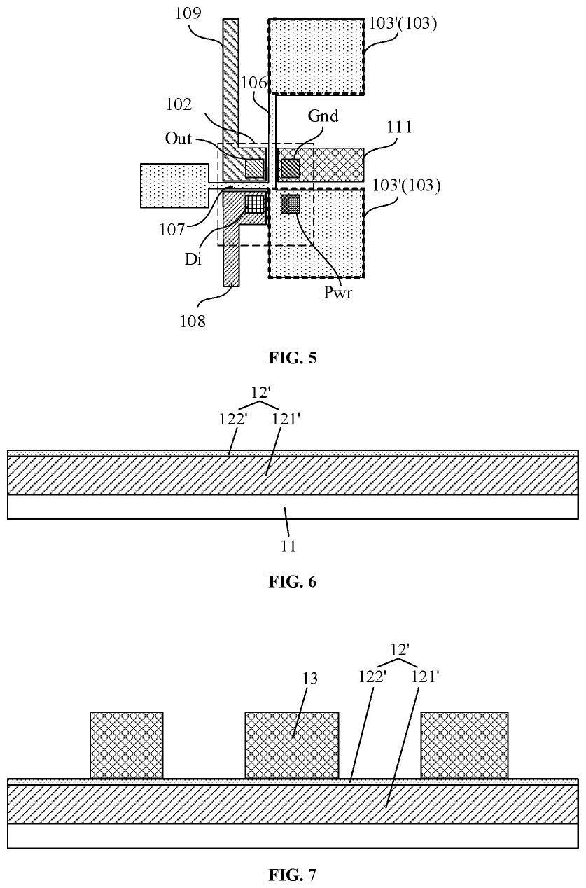

FIG. 6 is a schematic diagram of a wiring substrate according to some embodiments of the present disclosure after a metal film is formed in the wiring substrate. In some embodiments, as shown in FIG. 6, the alloy film 122′ is deposited on the surface, away from the substrate 11, of the body metal film by using a deposition process, and then the metal film 12′ is acquired. The metal film 12 ‘includes the body metal film 121’ and the alloy film 122′ that are stacked.

In S30, a first photoresist is coated on a side, facing away from the substrate 11, of the metal film, and a plurality of first photoresist bodies 13 spaced apart are formed by using a first mask to expose and develop the first photoresist, wherein the first photoresist bodies 13 are disposed at locations of the metal traces 12. As shown in FIG. 7, FIG. 7 is a schematic diagram of a wiring substrate according to some embodiments of the present disclosure after a first photoresist is formed in the wiring substrate.

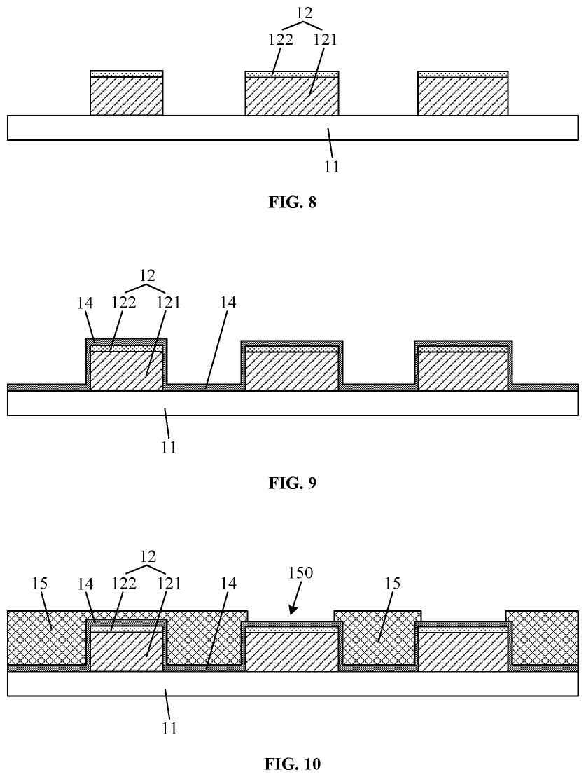

In S40, a plurality of metal traces 12 are acquired by etching the metal film other than the first photoresist body 13 and stripping the first photoresist body 13. The metal trace 12 includes the body metal layer 121 and the alloy layer 122 that are stacked, and the alloy layer 122 is disposed on the surface, away from the substrate 11, of the body metal layer 121. As shown in FIG. 8, FIG. 8 is a schematic diagram of a wiring substrate according to some embodiments of the present disclosure after a metal trace is formed in the wiring substrate.

In some embodiments of the present disclosure, the metal trace 12 with a predetermined thickness is acquired by using only one mask, which saves at least about 5 masks compared to the related art, greatly reducing the number of masks, lowering the cost, and improving the competitiveness of the product.

In some embodiments, the material of the insulative layer 15 includes white ink. S50 includes the following steps.

In a first step, an inorganic protective layer 14 is deposited on a side, facing toward the metal traces 12, of the substrate 11, and the inorganic protective layer 14 covers the metal traces 12 and the substrate 11. As shown in FIG. 9, FIG. 9 is a schematic diagram of a wiring substrate according to some embodiments of the present disclosure after an inorganic protective layer is formed in the wiring substrate. A thickness of the inorganic protective layer 14 is defined as desired. In some embodiments, the thickness of the inorganic protective layer 14 ranges from 8% to 12.5% of a thickness of the metal trace 12, e.g., the thickness of the inorganic protective layer 14 is not greater than 10% of the thickness of the metal trace 12. After the inorganic protective layer 14 is formed, the inorganic protective layer 14 protects the metal trace 12, such that the metal trace 12 is prevented from being eroded by water and oxygen in the subsequent process.

In a second step, white ink is formed on a side, facing away from the substrate 11, of the inorganic protective layer 14 by using a screen printing process, wherein a first aperture 150 is formed in the white ink. As shown in FIG. 10, FIG. 10 is a schematic diagram of a wiring substrate according to some embodiments of the present disclosure after white ink is formed in the wiring substrate. In some embodiments, the first aperture 150 exposes a portion of a surface of the inorganic protective layer 14, as shown in FIG. 10. At locations other than the first aperture 150, the white ink covers the inorganic protective layer 14, such that the white ink and the inorganic protective layer 14 provide double protection to the metal trace 12, and thus the metal trace 12 is prevented from being eroded by water and oxygen. By adopting the screen printing process, the white ink and the first aperture 150 are formed at one time. In this way, the use of mask exposure is avoided, such that the mask is saved, and thus the cost is reduced. In some embodiments, the white ink is coated on the inorganic protective layer 14, and the first aperture 150 is formed by using the mask, exposure, and development.

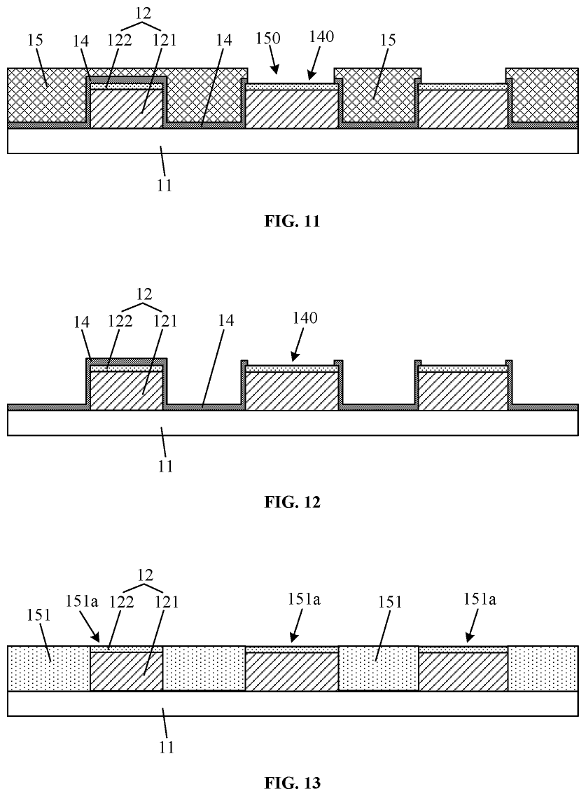

In a third step, a second aperture 140 is formed in the inorganic protective layer 14 by using a screen-printing wet-etching process. As shown in FIG. 11, FIG. 11 is a schematic diagram of a wiring substrate according to some embodiments of the present disclosure after a second aperture and white ink are formed in the wiring substrate. In some embodiments, as shown in FIG. 11, a wet etching paste is printed on the inorganic protective layer 14 exposed through the first aperture 150 by using a screen. The wet etching paste chemically reacts with the inorganic protective layer 14, and thus the inorganic protective layer 14 is etched away. In this way, the second aperture 140 is formed in a region, corresponding to the first aperture 150, of the inorganic protective layer 14, and the second aperture 140 exposes a portion of the surface of the metal trace 12. In the case where the second aperture 140 is formed by using the screen-printing wet-etching process, the use of the mask is avoided, and thus the cost is reduced.

In some other embodiments, the material of the insulative layer 15 includes white ink. S50 includes the following steps.

In a first step, an inorganic protective layer 14 is deposited on a side, facing toward the metal traces 12, of the substrate 11, and the inorganic protective layer 14 covers the metal traces 12 and the substrate 11, as shown in FIG. 9.

In a second step, a second aperture 140 is formed in the inorganic protective layer 14 by using a screen-printing wet-engraving process. As shown in FIG. 12, FIG. 12 is a schematic diagram of a wiring substrate according to some other embodiments of the present disclosure after a second aperture is formed in an inorganic protective layer. In some embodiments, as shown in FIG. 12, a wet etching paste is printed on the inorganic protective layer 14 above the metal traces 12 by using a screen. The wet etching paste reacts chemically with the inorganic protective layer 14, such that the inorganic protective layer 14 is etched away, and thus the second aperture 140 is formed in the inorganic protective layer 14. The second aperture 140 exposes a portion of the surface of the metal trace 12.

In a third step, white ink is formed on a side, facing away from the substrate 11, of the inorganic protective layer 14 by using a screen printing process, and a first aperture 150 is formed in the white ink, as shown in FIG. 11. In some embodiments, the white ink is formed on the side, facing away from the substrate 11, of the inorganic protective layer 14, the first aperture 150 is formed in the white ink, an overlapping region is present between the first aperture 150 and the second aperture 140, and the overlapping region between the first aperture 150 and the second aperture 140 exposes a portion of the surface of the metal trace 12, as shown in FIG. 11. In some embodiments, an orthographic projection of the first aperture 150 on the substrate 11 is overlapped with an orthographic projection of the second aperture 140 on the substrate 11.

In some other embodiments, the insulative layer 15 includes a photoresist layer 151 and a reflective layer 15, and the first aperture 150 includes a first sub-aperture 151a and a second sub-aperture 152a. S50 includes the following steps.

In a first step, a second photoresist is coated on a side, facing toward the metal traces 12, of the substrate 11, and a photoresist pattern region and a hollow-out region are formed by using a first mask, wherein the second photoresist in the photoresist pattern region forms the photoresist layer 151, and the hollow-out region forms the first sub-apertures 151a. As shown in FIG. 13, FIG. 13 is a schematic diagram of a wiring substrate according to some embodiments of the present disclosure after a photoresist layer is formed in the wiring substrate.

In some embodiments, as shown in FIG. 13, the second photoresist is coated on the side, on which the metal traces 12 are formed, of the substrate 11, and the photoresist patterned region and the hollow-out region are formed by using the first mask to expose and develop the second photoresist. The first mask used in this process is the same as the first mask in the process of FIG. 6 to FIG. 8, thus, the photoresist pattern region is disposed in a region other than the metal traces 12 and the hollow-out region is disposed above the metal traces 12. The second photoresist of the photoresist pattern region forms the photoresist layer 151, and the hollow-out region forms the first sub-aperture 151a. The first sub-aperture 151a exposes an entire surface of a side, away from the substrate 11, of the metal trace 12. In some embodiments, one of the second photoresist and the first photoresist is a positive photoresist and the other is a negative photoresist. By selecting the second photoresist opposite to the first photoresist, the same mask is used, such that the number of masks is reduced, and thus the cost is further saved. A thickness of the photoresist layer 151 is defined as desired, and the thickness of the photoresist layer 151 is equal to or greater than the thickness of the metal trace 12.

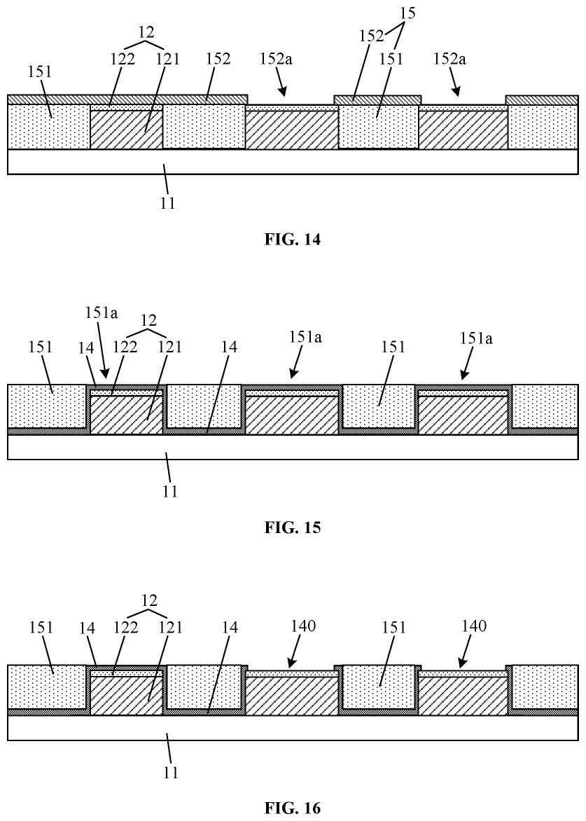

In a second step, the reflective layer 152 is formed on a side, facing away from the substrate 11, of the photoresist layer 151 by using a screen printing process. The second sub-aperture 152a is formed in the reflective layer 152, and an overlapped region is present between an orthographic projection of the second sub-aperture 152a on the substrate and an orthographic projection of the first sub-aperture 151a on the substrate. For example, the orthographic projection of the second sub-aperture 152a on the substrate 11 is within the orthographic projection of the first sub-aperture 151a on the substrate 11. The second sub-aperture 152a exposes a portion of the surface of the metal trace 12, as shown in FIG. 14, FIG. 14 is a schematic diagram of a wiring substrate according to some embodiments of the present disclosure after a reflective layer is formed in the wiring substrate. In some embodiments, the overlapping region between the first sub-aperture 151a and the second sub-aperture 152a forms the first aperture 150.

In other embodiments, the insulative layer 15 includes a photoresist layer 151 and a reflective layer 152, and the first aperture 150 includes a first sub-aperture 151a and a second sub-aperture 152a. S50 includes the following steps.

In a first step, an inorganic protective layer 14 is deposited on a side, facing toward the metal traces 12, of the substrate 11, and the inorganic protective layer 14 covers the metal traces 12 and the substrate 11, as shown in FIG. 9.

In a second step, a second photoresist is coated on a side, facing toward the inorganic protective layer 14, of the substrate 11, and a photoresist patterned region and a hollow-out region are formed by using a first mask, wherein the second photoresist in the photoresist patterned region forms the photoresist layer 151, and the hollow-out region forms the first sub-aperture 151a as shown in FIG. 15.

FIG. 15 is a schematic diagram of some embodiments of the present disclosure after a photoresist layer is formed. In some embodiments, as shown in FIG. 15, the second photoresist is coated on the inorganic protective layer 14, and the photoresist pattern region and the hollow-out region are formed by using the first mask to expose and develop the second photoresist. The photoresist pattern region is disposed in a region other than the metal traces 12, and the hollow-out region is disposed above the metal traces 12. The second photoresist of the photoresist pattern region forms the photoresist layer 151, the hollow-out region forms the first sub-aperture 151a, and the first sub-aperture 151a exposes an entire surface of a side, away from the substrate 11, of the metal trace 12. In some embodiments, one of the second photoresist and the first photoresist is a positive photoresist, and the other is a negative photoresist.

In a third step, the second aperture 140 is formed by removing at least a portion of the exposed inorganic protective layer 14 using a screen-printing wet-etching process, as shown in FIG. 16.

FIG. 16 is a schematic diagram of a wiring substrate according to some embodiments of the present disclosure after a second aperture is formed in an inorganic protective layer. In some embodiments, as shown in FIG. 6, a wet etching paste is printed on the inorganic protective layer 14 exposed through the first sub-aperture 151a by using a screen. The wet etching paste chemically reacts with the inorganic protective layer 14, and thus the inorganic protective layer 14 is etched away, such that the second aperture 140 is formed in a region, corresponding to the first sub-aperture 151a, of the inorganic protective layer 14, and the second aperture 140 exposes a portion of the surface of the metal trace 12. By forming the second aperture 140 using the screen-printing wet-etching process, the use of a photolithographic mask is avoided, and the cost is further reduced.

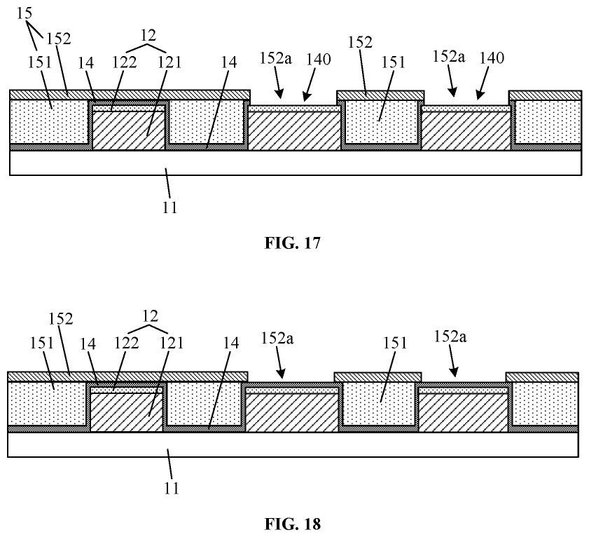

In a third step, the reflective layer 152 is formed on a side, away from the substrate 11, of the photoresist layer 151 by using a screen printing process, and the second sub-aperture 152a is formed in the reflective layer 152, as shown in FIG. 17.

FIG. 17 is a schematic diagram of some embodiments of the present disclosure after a reflective layer and a second aperture are formed. In some embodiments, as shown in FIG. 17, the reflective layer 152 is formed on the side, away from the substrate 11, of the photoresist layer 151 by using the screen printing process, and the second sub-aperture 152a is formed in the reflective layer 152. An overlapping region is present between the second sub-aperture 152a and the second aperture 140, and the overlap overlapping between the second sub-aperture 152a and the second aperture 140 exposes a portion of the surface of the metal trace 12. In some embodiments, an orthographic projection of the second sub-aperture 152a on the substrate 11 may overlap with an orthographic projection of the second aperture 140 on the substrate 11.

In some other embodiments, the insulative layer 15 includes a photoresist layer 151 and a reflective layer 152, and the first aperture 150 includes a first sub-aperture 151a and a second sub-aperture 152a. S50 includes the following steps.

In a first step, an inorganic protective layer 14 is deposited on a side, facing toward the metal traces 12, of the substrate 11, and the inorganic protective layer 14 covers the metal traces 12 and the substrate 11, as shown in FIG. 9.

In a second step, a second photoresist is coated on a side, facing toward the inorganic protective layer 14, of the substrate 11, and a photoresist patterned region and a hollow-out region are formed by using a first mask. The second photoresist in the photoresist patterned region forms the photoresist layer 151, and the hollow-out region forms the first sub-aperture 151a, as shown in FIG. 15.

In a third step, the reflective layer 152 is formed on a side, away from the substrate 11, of the photoresist layer 151 by using a screen printing process, and the second sub-aperture 152a is formed in the reflective layer 152, as shown in FIG. 18.

FIG. 18 is a schematic diagram of some other embodiments of the present disclosure after a reflective layer is formed. In some embodiments, as shown in FIG. 18, the reflective layer 152 is formed on the side, away from the substrate 11, of the photoresist layer 151 by using the screen printing process, the second sub-aperture 152a is formed in the reflective layer 152, and an overlapping region exits between an orthographic projection of the second sub-aperture 152a on the substrate and an orthographic projection of the first sub-aperture 151a on the substrate. For example, the orthographic projection of the second sub-aperture 152a on the substrate 11 is within the orthographic projection of the first sub-aperture 151a on the substrate 11. The second sub-aperture 152a exposes a portion of the surface of the inorganic protective layer 14.

In a fourth step, the second aperture 140 is formed by removing at least a portion of the exposed inorganic protective layer 14 using a screen-printing wet-etching process, as shown in FIG. 17.

In some embodiments, as shown in FIG. 11, FIG. 14, and FIG. 17, the distance between the surface of the side, away from the substrate 11, of the insulative layer 15 and the substrate 11 is equal to or greater than the distance between the surface of the side, away from the substrate 11, of the metal trace 12 and the substrate 11, and the surface, away from the substrate 11, of the insulative layer 15 is capable of reflecting light. In FIG. 11, the material of the insulative layer 15 includes white ink, and the surface of the white ink is capable of reflecting light. In FIG. 14 and FIG. 17, the reflective layer 152 in the insulative layer 15 is capable of reflecting light.

In some embodiments, the method for preparing the wiring substrate further includes: performing an electroless nickel immersion gold process on an exposed surface of the metal trace 12. This step includes: growing a nickel-gold layer on the exposed surface of the metal trace 12, where the nickel-gold layer serves as an oxidation protective layer 16, as shown in FIG. 11, FIG. 14, and FIG. 17. In some embodiments, a nickel (Ni) layer is first formed on the exposed surface of the metal trace 12 by chemical plating, with a thickness of the nickel layer ranging from 3 μm to 5 μm; and then a gold (Au) layer is plated on a surface of the nickel layer by a displacement reaction, with a thickness of the gold layer of about 0.03 μm, such that the oxidation protective layer 16 is acquired, and the oxidation protective layer 16 includes the nickel layer and the gold layer. An orthographic projection of the oxidation protective layer 16 on the wiring substrate 11 is within a range of the orthographic projection of the metal trace 12 on the wiring substrate 11, and the oxidation protective layer 16 is in direct contact with the metal trace 12 running through the first aperture 150. The material of the oxidation protective layer 16 includes nickel. For example, the material of the oxidation protective layer 16 includes a nickel-gold (NiAu) layer. A thickness of the oxidation protective layer 16 ranges from 4 μm to 5 μm (including endpoint values).

In some embodiments, prior to performing the electroless nickel immersion gold process on the exposed surface of the metal trace 12, the method for preparing the wiring substrate further includes: employing an acid washing process to acid wash the surface of the metal trace 12 that is exposed through the first aperture 150. By controlling the period of the acid washing, a thickness of a reaction between the acid and the metal trace 12 is controlled, such that oxidized components on the surface of the metal trace 12 due to exposure to air are removed, which ensures the reliability of the electrical connection and the low resistance characteristics of the metal trace 12. In some embodiments shown in FIG. 1 to FIG. 3, a thickness of the alloy layer is thin, and thus the alloy layer 122 exposed by the first aperture in the metal trace 12 is removed in whole or in part by corrosion after the acid washing process, such that the oxidation protective layer 16 is in direct contact with the body metal layer 121.

In the embodiments of the present disclosure, only one mask is needed to form the wiring substrate. Further, the metal trace with a predetermined thickness is acquired, and at least twofold protection is provided for the metal trace. In this way, the metal trace is prevented from being eroded by water and oxygen during the process, such that the product performance is improved, and thus the cost is reduced.

In the description of the present specification, it should be understood that orientations or positional relationships indicated by the terms “center,” “longitudinal,” “transverse,” “length,” “width,” “thickness,” “up,” “down,” “front,” “back,” “left,” “right,” “vertical,” “horizontal,” “top,” “bottom,” “inside,” “outer,” “clockwise,” “counterclockwise,” “axial,” “radial,” “circumferential,” and the like are orientations or positional relationships based on the accompanying drawings, are intended only to facilitate description of the present disclosure and to simplify the description, and are not intended to indicate or imply that the referred device or element must be in a particular orientation or constructed and operated in a particular orientation, and therefore cannot be construed as a limitation of the present disclosure.

Furthermore, the terms “first” and “second” are only used for descriptive purposes, and cannot be understood as indicating or implying relative importance. Accordingly, a feature defined by “first” or “second” may expressly or implicitly include one or more such features. In the present disclosure, the term “a plurality of” refers to two or more, unless expressly defined otherwise.

In the present disclosure, unless otherwise expressly defined and limited, the terms “mount,” “couple,” “connect,” “fix,” and the like should be understood in a broad sense. For example, it may be a fixed connection, a detachable connection, or integrated; it may be a mechanical connection, electrical connection, or communication; it may be directly connected or indirectly connected through an intermediary, it may be the connection between two components or the interaction between the two components. For those skilled in the art, the specific meaning of the above terms in the present disclosure may be understood according to actual needs.

In the present disclosure, unless otherwise expressly defined and limited, a first feature being “over” or “under” a second feature includes that the first feature is in direct contact with the second feature, or the first feature and the second feature are not in direct contact but in contact through another feature between them. Furthermore, the first feature being “above,” “up,” and “over” the second feature includes that the first feature is directly above and diagonally above the second feature, or simply indicates that the first feature is horizontally higher than the second feature. The first feature being “below,” “under,” and “underneath” the second feature includes that the first feature is directly below and diagonally below the second feature, or simply indicates that the first feature is horizontally smaller than the second feature.

The above disclosure provides various embodiments or examples to realize different structures of the present disclosure. To simplify the present disclosure, the parts and arrangements of particular examples are described above. They are, of course, only examples and are not intended to limit the present disclosure. In addition, the present disclosure may repeat reference numerals and/or reference letters in different examples, and such repetition is for simplicity and clarity and is not in itself indicative of a relationship between the various implementations and/or arrangements discussed.

Described above are merely some exemplary embodiments of the present disclosure, but the protection scope of the present disclosure is not limited thereto. Variations or substitutions thereof may readily be conceived by any person skilled in the art within the scope of the art disclosed in this disclosure, which shall be covered within the protection scope of the present disclosure. Therefore, the protection scope of the present disclosure shall be subject to the protection scope of the claims.

1. A wiring substrate, comprising:
a substrate;
a plurality of metal traces disposed on a side of the substrate; and
an insulative layer disposed on the same side of the substrate as the plurality of metal traces, wherein the insulative layer is disposed in a region other than the metal traces and on a portion of surfaces of the metal traces, a distance between a surface, away from the substrate, of the insulative layer and the substrate is greater than a distance between a surface, away from the substrate, of the metal trace and the substrate, the surface, away from the substrate, of the insulative layer is capable of reflecting light, and a first aperture is formed in the insulative layer, the first aperture exposing a portion of the surface of each of the metal traces.

2. The wiring substrate according to claim 1, wherein a material of the insulative layer comprises white ink, and the insulative layer covers the metal traces at locations other than the first aperture.

3. The wiring substrate according to claim 1, wherein the insulative layer comprises a photoresist layer and a reflective layer; wherein
the photoresist layer is disposed in the region other than the metal traces, and the first aperture comprises a first sub-aperture, the first sub-aperture running through the photoresist layer; and
the reflective layer is at least disposed on a surface of a side, away from the substrate, of the photoresist layer.

4. The wiring substrate according to claim 3, wherein the reflective layer covers the photoresist layer and the metal traces, the first aperture comprises a second sub-aperture, the second sub-aperture running through the reflective layer, and an overlapping region being present between an orthographic projection of the second sub-aperture on the substrate and an orthographic projection of the first sub-aperture on the substrate.

5. The wiring substrate according to claim 4, wherein a material of the reflective layer comprises white ink.

6. The wiring substrate according to claim 1, wherein each of the metal traces comprises a body metal layer and an alloy layer that are stacked, the alloy layer being disposed on a surface, away from the substrate, of the body metal layer.

7. The wiring substrate according to claim 1, wherein a thickness of each of the metal traces ranges from 5 μm to 8.5 μm.

8. The wiring substrate according to claim 1, further comprising: an oxidation protective layer, wherein the oxidation protective layer is disposed in an exposed region of the metal trace, the oxidation protective layer is in direct contact with the metal trace, a material of the oxidation protective layer comprises nickel and gold, and a thickness of the oxidation protective layer ranges from 4 μm to 5 μm.

9. The wiring substrate according to claim 1, further comprising: an inorganic protective layer, wherein the inorganic protective layer covers the metal traces and an exposed surface of the substrate, the insulative layer is disposed on a side, facing away from the substrate, of the inorganic protective layer, and a second aperture is formed in the inorganic protective layer, an overlapping region being present between an orthographic projection of the second aperture on the substrate and an orthographic projection of the first aperture on the substrate.

10. The wiring substrate according to claim 9, wherein a material of the inorganic protective layer comprises one or more of silicon oxide, silicon nitride, or silicon oxynitride.

11. The wiring substrate according to claim 1, wherein
the plurality of metal traces comprise a power signal line, an address signal line, a common voltage signal line, a cascade line, and a feedback signal line;
the plurality of metal traces form a plurality of first pad groups and a plurality of second pad groups through a surface exposed by the first aperture, wherein the plurality of first pad groups are configured to be coupled to a micro driver chip, and the plurality of second pad groups are configured to be coupled to a light-emitting element;
each of the plurality of first pad groups comprises a power supply pad, an output pad, an address pad, and a ground pad, wherein the power supply pad is connected to the power signal line, the ground pad is connected to the common voltage signal line, and the output pad is connected to at least one pad of one of the second pad groups; and
the plurality of first pad groups are cascaded, and in the plurality of cascaded first pad groups, the address pad of a first one of the first pad groups is connected to the address signal line, the output pad of a last one of the first pad groups is connected to the feedback signal line, and the output pad of an n^{th} cascaded one of the first pad groups is connected to the address pad of a (n+1)^{th} cascaded one of the first pad groups by one of the cascade lines, wherein n is a positive integer.

12. A method for preparing a wiring substrate, comprising
forming a plurality of metal traces on a side of a substrate; and
forming an insulative layer on the side, on which the plurality of metal traces are formed, of the substrate, wherein the insulative layer is disposed in a region other than the metal traces and on a portion of surfaces of the metal traces, a distance between a surface of a side, away from the substrate, of the insulative layer and the substrate is greater than a distance between a surface of a side, distal form the substrate, of the metal trace and the substrate, the surface, away from the substrate, of the insulative layer is capable of reflecting light, and a first aperture is formed in the insulative layer, the first aperture exposing a portion of the surface of each of the metal traces.

13. The method according to claim 12, wherein forming the plurality of metal traces on the side of the substrate comprises:
forming a body metal film with a predetermined thickness on a side of the substrate;
acquiring a metal film comprising the body metal film and an alloy film by depositing the alloy film on a surface, away from the substrate, of the body metal film;
forming a plurality of first photoresist bodies spaced apart by coating a first photoresist on a side, facing away from the substrate, of the metal film and using a first mask to expose and develop the first photoresist; and
acquiring the plurality of metal traces by etching the metal film other than the first photoresist bodies and stripping the first photoresist bodies.

14. The method according to claim 13, wherein forming the body metal film with the predetermined thickness on the side of the substrate comprises:
forming the body metal film with the predetermined thickness on the side of the substrate by using a deposition process multiple times; or
acquiring the body metal film with the predetermined thickness by depositing a first metal film on the side of the substrate and forming a second metal film on a surface, away from the substrate, of the first metal film using an electroplating process, wherein the body metal film comprises the first metal film and the second metal film that are stacked.

15. The method according to claim 13, wherein
the insulative layer is white ink; and
forming the insulative layer on the side, facing toward the plurality of metal traces, of the substrate comprises:
depositing an inorganic protective layer on the side, facing toward the plurality of metal traces, of the substrate, wherein the inorganic protective layer covers the metal traces and the substrate;
forming white ink on a side, facing away from the substrate, of the inorganic protective layer by using a screen printing process, wherein the first aperture is formed in the white ink; and
forming a second aperture in the inorganic protective layer by using a screen-printing wet-etching process.

16. The method according to claim 13, wherein
the insulative layer comprises a photoresist layer and a reflective layer, and the first aperture comprises a first sub-aperture and a second sub-aperture; and
forming the insulative layer on the side, facing toward the plurality of metal traces, of the substrate comprises:
coating a second photoresist on the side, facing toward the plurality of metal traces, of the substrate, and forming a photoresist patterned region and a hollow-out region by using a first mask, wherein the second photoresist in the photoresist patterned region forms the photoresist layer, the hollow-out region forms the first sub-aperture, and one of the second photoresist and the first photoresist is a positive photoresist and the other is a negative photoresist; and
forming the reflective layer on a side, away from the substrate, of the photoresist layer by using a screen printing process, wherein the second sub-aperture is formed in the reflective layer, an overlapping region being present between an orthographic projection of the second sub-aperture on the substrate and an orthographic projection of the first sub-aperture on the substrate.

17. The method according to claim 13, wherein
the insulative layer comprises a photoresist layer and a reflective layer, and the first aperture comprises a first sub-aperture and a second sub-aperture; and
forming the insulative layer on the side, facing toward the plurality of metal traces, of the substrate comprises:
depositing an inorganic protective layer on the side, facing toward the plurality of metal traces, of the substrate, wherein the inorganic protective layer covers the metal traces and the substrate;
coating a second photoresist on a side, facing toward the inorganic protective layer, of the substrate, and forming a photoresist patterned region and a hollow-out region by using a first mask, wherein the second photoresist in the photoresist patterned region forms the photoresist layer, the hollow-out region forms the first sub-aperture, and one of the second photoresist and the first photoresist is a positive photoresist and the other is a negative photoresist;
forming a second aperture by removing at least a portion of the exposed inorganic protective layer using a screen-printing wet-etching process; and
forming the reflective layer on a side, away from the substrate, of the photoresist layer by using a screen printing process, wherein the second sub-aperture is formed in the reflective layer.

18. The method according to claim 12, further comprising:
performing an electroless nickel immersion gold process on exposed surfaces of the metal traces.

19. A light-emitting panel, comprising: a wiring substrate, and a plurality of light-emitting diode chips, wherein;
the wiring substrate comprises:
a substrate;
a plurality of metal traces disposed on a side of the substrate; and
an insulative layer disposed on the same side of the substrate as the plurality of metal traces, wherein the insulative layer is disposed in a region other than the metal traces and on a portion of surfaces of the metal traces, a distance between a surface, away from the substrate, of the insulative layer and the substrate is greater than a distance between a surface, away from the substrate, of the metal trace and the substrate, the surface, away from the substrate, of the insulative layer is capable of reflecting light, and a first aperture is formed in the insulative layer, the first aperture exposing a portion of the surface of each of the metal traces; and
the plurality of light-emitting diode chips are correspondingly connected to the plurality of metal traces.

20. A display device, comprising: the light-emitting panel as defined in claim 19.
